(19) United States
(12) Patent Application Publication
(10) Pub. No.: US 2009/0140423 A1
(43) Pub. Date: Jun. 4, 2009

(54) UNDERBUMP METALLURGY EMPLOYING SPUTTER-DEPOSITED NICKEL TITANIUM ALLOY

(75) Inventors: Luc Belanger, Granby (CA); Srinivasa S.N. Reddy, Lagrangeville, NY (US); Da-Yuan Shih, Poughkeepsie, NY (US); Brian R. Sundlof, Beacon, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/947,070

(22) Filed: Nov. 29, 2007

(51) Int. Cl. H01L 23/48; H01L 21/44

(52) U.S. Cl. 257/738; 438/614; 257/E21.476; 257/E23.01

(57) ABSTRACT

A a metallic adhesion layer is formed on a last level metal plate exposed in an opening of a passivation layer. A Ni—Ti alloy in which the weight percentage of Ti is from about 6.5% to about 30% is deposited by sputtering onto the metallic adhesion layer to form an underbump metallic layer. A wetting layer comprising Cu or Ag or Au is deposited on top of Ni—Ti layer by sputtering. A C4 ball is applied to a surface of the wetting layer for C4 processing. The sputter deposition of the Ni—Ti alloy offers economic and performance advantages relative to known methods in the art since the Ni—Ti alloy in the composition of the present invention is non-magnetic and easy to sputter, and the consumption of the inventive Ni—Ti alloy is limited during C4 processing. Also, Sn in the solder reacts uniformly with both Ni and Ti and the consumption of Ni—Ti by Sn solder is less than that for pure Ni.

### RELATED APPLICATIONS

The present application is related to a co-pending U.S. patent application Ser. No. ______ (Attorney Docket No. FIS920070248US1 (SSMP 21267)), which is incorporated herein by reference.

### FIELD OF THE INVENTION

The present invention relates to semiconductor structures, and particularly to underbump metallurgy (UBM) employing a sputter-deposited nickel titanium alloy, and structures and methods thereof.

### BACKGROUND OF THE INVENTION

Once formation of semiconductor devices and interconnects on a semiconductor wafer (substrate) is completed, the semiconductor wafer is diced into semiconductor chips, or “dies.” Functional semiconductor chips are then packaged to facilitate mounting on a circuit board. A package is a supporting element for the semiconductor chip that provides mechanical protection and electrical connection to an upper level assembly system such as the circuit board. One typical packaging technology is Controlled Collapse Chip Connection (C4) packaging, which employs C4 balls each of which contacts a C4 pad on the semiconductor chip and another C4 pad on a packaging substrate. The packaging substrate may then be assembled on the circuit board.

Thus, the packaging substrate facilitates formation of an electrical link between the semiconductor chip and a system board of a computer. A semiconductor chip is mounted on a die foot print area located on a top surface of the packaging substrate. The die foot print area contains C4 pads on which a semiconductor chip may be attached by C4 bonding.

A typical semiconductor chip employing a packaging substrate may comprise about 5,000 input/output nodes. Each of these nodes are electrically connected to a C4 pad on a top surface of the semiconductor chip in a two dimensional array. Typical two dimensional array configurations for the C4 pads include 4 on 8 configuration, which employs C4 solder balls having a diameter of 4 mils (approximately 100 microns) and a pitch of 8 mils (approximately 200 microns) in a rectangular array, and 3.0 on 6 configuration, which employs C4 solder balls having a diameter of 3.0 mils (approximately 75 microns) and a pitch of 6 mils (approximately 150 microns) in a rectangular array. Thus, more than 5,000 C4 solder balls may be formed on the semiconductor chip, which may be typically about 2 cm×2 cm in size.

The collection of metallic layers employed to attach a C4 ball to a semiconductor chip is called an “underbump metallurgy structure,” or a “UBM structure” in the art. A typical underbump metallurgy structure includes a stack of a metallic adhesion layer, an underbump metallic layer, and an optional wetting layer. The metallic adhesion layer is formed directly on the semiconductor chip and comprises an adhesion promoting metallic material such as Ti, TiW, or TiN. The underbump metallic layer may comprise an elemental metal such as Cu or Ni, which may be deposited by electroplating or by sputtering. Alternately, the underbump metallic layer may comprise a metal compound such as a Ni—Si alloy, Ni—V alloy or a Ni—W alloy, which may be deposited only by sputtering since electroplating of these alloys is either impossible or faces technical difficulties. In case the underbump metallic layer comprises any other material than pure elemental Cu or pure elemental Ni, a wetting layer is needed to promote adhesion of a C4 ball with the underbump metallic layer. The wetting layer typically comprises elemental Cu or elemental Ag or elemental Au.

While formation of an underbump metallic layer comprising pure elemental Cu or pure elemental Ni by electroplating or sputtering may seem to be the most inexpensive method of forming the underbump metallic layer, both choices have inherent disadvantages. Pure elemental Cu is known to react readily with lead-free C4 balls, which typically comprise a Sn—Cu—Ag alloy, in which the concentration of Cu is about 0.7 atomic percent and the concentration of Ag is from about 0.5 atomic percent to about 3.5 atomic percent. About 2.5 μm to 5 μm of pure elemental Cu is consumed in a reaction with a C4 ball in a typical C4 bonding process. Due to such high consumption rate of Cu, a thick Cu film exceeding 5 μm in thickness is required for the underbump metallic layer. Further, consumption of Cu is not limited in subsequent thermal processing, which raises reliability issues.

In the case of pure elemental Ni, the amount of consumption in a reaction with a C4 ball is less than pure elemental Cu, and may be from about 1.0 μm to abut 2.0 μm. However, pure Ni is magnetic and renders sputtering of Ni technically difficult. While experiments reporting successful sputtering of Ni have been reported, commercial Ni sputtering process is expensive due to the magnetic nature of pure elemental Ni. Thus, deposition of pure elemental Ni is almost always performed by electroplating in commercial production of semiconductor chips. The higher cost of electroplating compared to sputtering renders use of pure elemental Ni commercially undesirable.

The use of a non-magnetic alloy such as a Ni—Si alloy or Ni—V alloy or Ni—W alloy enables use of sputtering for formation of the underbump metallic layer, along with a wetting layer such as Cu or Ag or Au. However, Sn in the solder reacts with only the Ni portion of the alloy and the remaining alloy becomes progressively richer in non-reacting elements Si or V or W. This non-uniform reaction is not desirable and may lead to reliability concerns.

In view of the above, there exists a need for an underbump metallurgy structure that reacts uniformly with Sn-based solder and results in consumption of only a small quantity of material due to interaction with a C4 ball, and requires as few processing steps as possible, and provides a stable structure in which consumption of material does not continue with usage at a high temperature.

Further, there exists a need for methods of forming such non-magnetic underbump metallurgy structure in an economical manner, while minimizing process complexity.

### SUMMARY OF THE INVENTION

The present invention addresses the needs described above by providing a method of forming an underbump metallurgy structure in which a non-magnetic Ni—Ti alloy is deposited on a metallic adhesion layer by sputtering, in which the composition of the Ni—Ti alloy is selected to minimize reaction with a C4 ball.

In the present invention, a metallic adhesion layer is formed on a last level metal plate exposed in an opening of a passivation layer. A Ni—Ti alloy in which the weight percentage of Ti is from about 6.5% to about 30% is deposited by sputtering onto the metallic adhesion layer to form an underbump metallic layer. A wetting layer comprising Cu or Ag or Au is deposited on top of Ni—Ti layer by sputtering. A C4 ball is applied to a surface of the wetting layer for C4 processing. The sputter deposition of the Ni—Ti alloy offers economic and performance advantages relative to known methods in the art since the Ni—Ti alloy in the composition of the present invention is non-magnetic and easy to sputter, and the consumption of the inventive Ni—Ti alloy is limited during C4 processing. Also, Sn in the solder reacts uniformly with both Ni and Ti and the consumption of Ni—Ti by Sn solder is less than that for pure Ni.

According to an aspect of the present invention, a semiconductor structure is provided, which comprises:

a metallic adhesion layer located on a semiconductor chip;

a Ni—Ti alloy layer abutting the metallic adhesion layer, wherein a weight percentage of Ti in the Ni—Ti alloy layer is from about 6.5% to about 30%; and

a wetting layer of comprising one of pure Cu, pure Ag, or pure Au

a C4 ball abutting the wetting layer.

According to another aspect of the present invention, a method of forming a semiconductor structure is provided, which comprises:

forming a metallic adhesion layer directly on a semiconductor chip;

forming a Ni—Ti alloy layer directly on the metallic adhesion layer by sputtering, wherein a weight percentage of Ti in the Ni—Ti alloy is from about 6.5% to about 30%;

forming a wetting layer comprising pure Cu or pure Ag or pure Au directly on the Ni—Ti alloy layer; and

applying a C4 ball directly on the wetting layer.

### BRIEF DESCRIPTION OF THE DRAWINGS

FIG. 1 shows a vertical cross-sectional view of an exemplary semiconductor structure according to the present invention prior to dicing and application of a C4 ball.

FIG. 2 shows a phase diagram of the Ni—Ti alloy system.

FIG. 3 is a magnetic phase diagram of the Ni—Ti alloy system.

FIG. 4 shows a vertical cross-sectional view of the exemplary semiconductor structure according to the first embodiment of the present invention after dicing and application of a C4 ball and prior to a reflow.

FIG. 5 shows a vertical cross-sectional view of the exemplary semiconductor structures after the reflow.

### DETAILED DESCRIPTION OF THE INVENTION

As stated above, the present invention relates to underbump metallurgy (UBM) employing a sputter-deposited nickel titanium alloy and structure and methods thereof, which are now described in detail with accompanying figures.

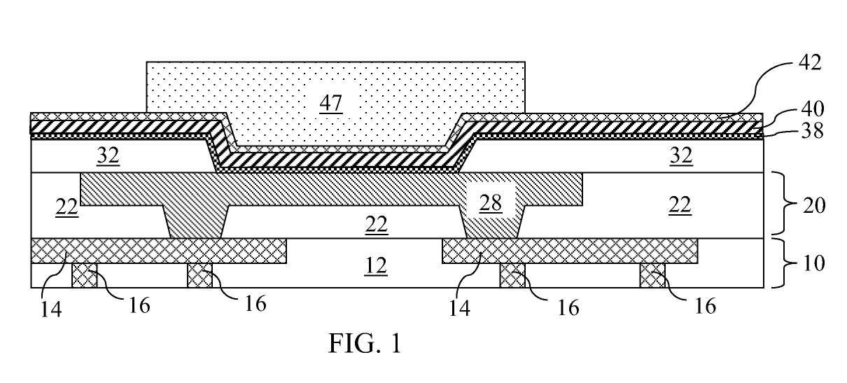

Referring to FIG. 1, an exemplary semiconductor structure comprises a back-end-of-line (BEOL) interconnect structure 10, a last level interconnect structure 20, and a dielectric passivation layer 32 that are formed on a semiconductor substrate (not shown). Semiconductor devices (not shown) are formed on the semiconductor substrate by employing semiconductor manufacturing processes known in the art. Typically, additional BEOL interconnect structures (not shown) are present between the semiconductor devices and the BEOL interconnect structure 10. The additional BEOL interconnect structures facilitate wiring of the semiconductor devices.

The BEOL interconnect structure 10 includes a back-end-of-line (BEOL) dielectric layer 12, back-end-of-line (BEOL) metal lines 14, and back-end-of-line (BEOL) metal vias 16. The BEOL metal lines 14 and the BEOL metal vias 16 are embedded in the BEOL dielectric layer 12. The BEOL dielectric layer may comprise silicon oxide or a low-k dielectric material known in the art. The BEOL metal lines 14 and the BEOL metal via 16 comprise a conductive metal such as Cu, and are formed by methods well known in the art.

The last level interconnect structure 20 includes a last level dielectric layer 22 and a last level metal plate 28. The last level dielectric layer 22 comprises a dielectric material such as silicon oxide. The last level metal plate 28 comprises a metal such as aluminum. Typically, the last level metal plate 28 is integrally formed with at least one via that electrically connects the last level metal plate 28 with the BEOL metal lines 14.

The dielectric passivation layer 32 comprises an impervious dielectric material that blocks ingress of moisture and oxygen into the last level interconnect structure 20. Exemplary impervious dielectric materials include silicon nitride. The dielectric passivation layer 32 may be a homogeneous layer comprising the impervious dielectric material, or may be a stack of multiple dielectric material layers including an impervious dielectric material layer. The thickness of the dielectric passivation layer 32 may be from about 2.0 μm to about 40 μm, and typically from about 4.0 μm to about 20 μm.

The dielectric passivation layer 32 has an opening that exposes a top surface of the last level metal plate 28. Typically, the dimension of the opening, e.g., a diameter of the opening, is from about 50 μm to about 100 μm. The opening is formed by lithographic patterning of a photosensitive resist that is removed after patterning of the opening, or a photosensitive polyimide which may form a part of the passivation layer 32.

A metallic adhesion layer 38 is deposited by chemical vapor deposition (CVD) or physical vapor deposition (PVD), i.e., sputtering. The metallic adhesion layer 38 comprises a metallic material that provides good adhesion to underlying structures including the last level metal plate 28 and the dielectric passivation layer 32. Exemplary materials for the metallic adhesion layer 38 comprise Ti, TiN, and TiW. The thickness of the metallic adhesion layer 38 may be from about 100 nm to about 500 nm, although lesser and greater thicknesses are also explicitly contemplated herein.

A Ni—Ti alloy layer 40 is formed directly on the metallic adhesion layer 38 by sputtering, i.e., physical vapor deposition. The semiconductor substrate, on which the BEOL interconnect structure 10, the last level interconnect structure 20, the dielectric passivation layer 32, and the metallic adhesion layer 38 are located, is placed in a vacuum chamber (not shown) having a sputter target (not shown). The sputter target contains a Ni—Ti alloy having a weight percentage of Ti from about 6.5% to about 30%. The material in the sputter target is sputtered onto the metallic adhesion layer 38 in an ultra-high vacuum (UHV) environment. Tools configured to accommodate a sputtering target and provide sputtering of the material in the sputtering target onto a substrate surface in a UHV environment are commercially available.

The weight percentage of Ti from about 6.5% to about 30% in the Ni—Ti alloy has been empirically selected based on empirical data from experiments leading to the present invention and consideration for providing a non-magnetic alloy for ease of the sputtering process employed in the formation of the Ni—Ti alloy layer 40.

A wetting layer 42 is formed directly on the Ni—Ti alloy layer 40. The wetting layer 42 comprises an elemental metal. For example, the wetting layer 42 may comprise pure Cu or pure Ag or pure Au. The wetting layer 42 may be deposited by electroplating, or preferably, by sputter deposition, i.e., physical vapor deposition (PVD), to reduce the processing cost. The thickness of the wetting layer 42 may be from about 0.1 μm to about 1.0 μm, and preferably from about 0.1 μm to about 0.6 μm, although lesser and greater thicknesses are also contemplated herein.

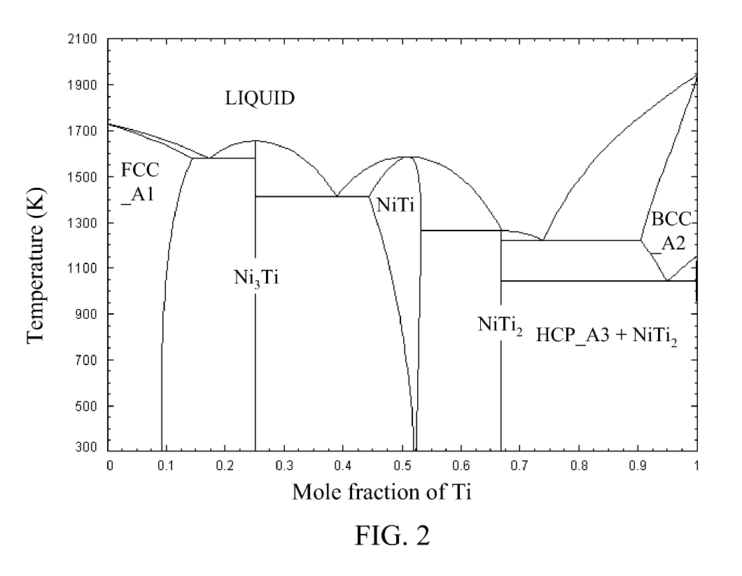

Referring to FIG. 2, a binary phase diagram of a Ni—Ti alloy system shows multiple phases of Ni—Ti alloys including Ni₃Ti, NiTi, and NiTi₂ and displaying various crystallographic structures such as the face-centered cubic (fc.c.) structure, the body-centered cubic (b.c.c.) structure, and the hexagonal close packed (h.c.p.) structure. Multiple eutectic systems among elemental Ni, Ni₃Ti, NiTi, NiTi₂, and elemental Ti are also shown. Typically, a Ni—Ti alloy sputter target having a weight percentage of Ti from about 6.5% to about 30% contains either a (Ni—Ti) solid solution or mixture of (Ni—Ti) solid solution and Ni₃Ti or mixture of Ni₃Ti and NiTi.

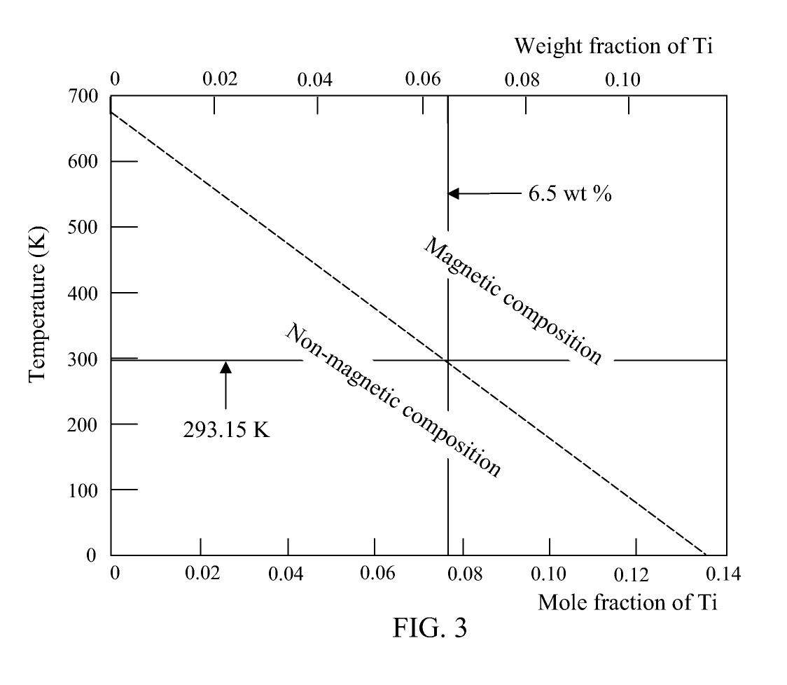

Referring to FIG. 3, the Ni—Ti alloy system displays a concentration dependent Curie temperature, below which the Ni—Ti alloy of a given concentration is ferromagnetic. The higher the weight percentage of Ni, the higher Curie temperature of the Ni—Ti alloy. At and above room temperature, (i.e., 293.15K, which is 20° C.), a Ni—Ti alloy is non-magnetic if the weight percentage of Ti is above 6.5%. By selecting a weight percentage of Ti about 6.5% or more, the Ni—Ti alloy is non-magnetic at or above room temperature. The material of the sputter target, which is a Ni—Ti alloy with a weight percentage of Ti about 6.5% or more, is thus non-magnetic, and complications of a sputtering process that would be encountered during a sputter deposition of a magnetic alloy is avoided. The upper bound of the weight percentage range of Ti is determined by a need to limit the amount of brittle intermetallic compounds Ni₃Ti and NiTi in the film. What is most desired is the alloy containg less than 10 wt % Ti which consists mostly of non-magnetic solid solution of (Ni—Ti) and small amounts of Ni₃Ti.

Referring back to FIG. 1, the thickness of the Ni—Ti alloy layer 40 may be from about 1.0 μm to about 4.0 μm, and preferably from about 1.0 μm to about 3.0 μm, and more preferably from about 1.0 μm to about 2.0 μm. A photoresist 47 is applied over the wetting layer 42 and lithographically patterned so that the region above the opening in the passivation layer 32 is covered with the photoresist 47, while the photoresist 47 is removed from an area outside the opening. The exposed portions of the wetting layer 42, the Ni—Ti layer 40, and the metallic adhesion layer 38 outside the area of the photoresist 47 are etched. The etch may be an anisotropic etch, and may be selective to the passivation layer 32. The photoresist 47 is subsequently removed.

Typically, the semiconductor substrate and the structures thereupon, which include the BEOL interconnect structure 10, the last level interconnect structure 20, the dielectric passivation layer 32, the metal adhesion layer 38, and the Ni—Ti alloy layer 40, are diced so that multiple semiconductor chips are separated along dicing channels. Typically, each semiconductor chip is identical to the rest of the semiconductor chips. Each semiconductor chip comprises portions of the BEOL interconnect structure 10, the last level interconnect structure 20, the dielectric passivation layer 32, the metal adhesion layer 38, and the Ni—Ti alloy layer 40 within dicing channels that define boundaries between adjacent semiconductor chips.

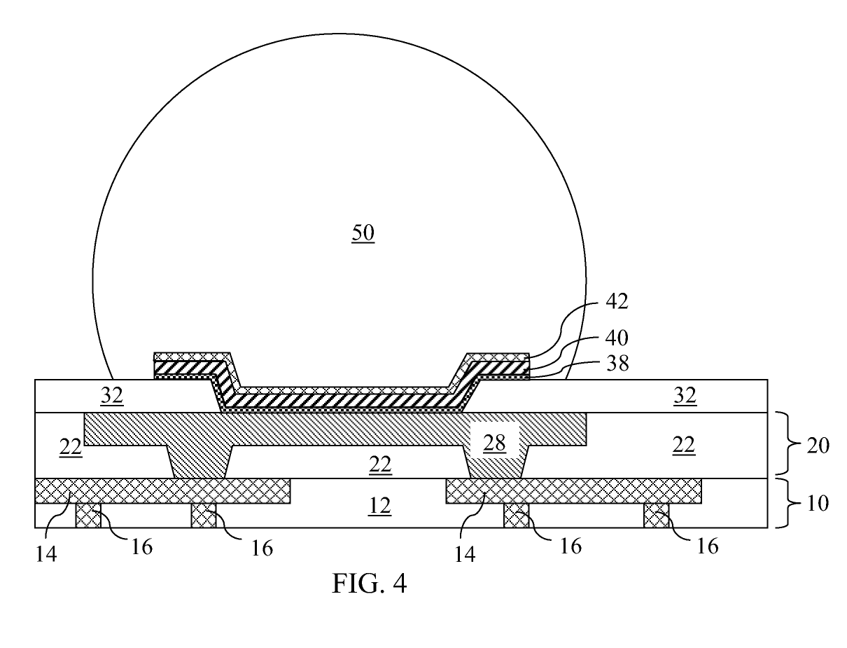

Referring to FIG. 4, a C4 ball 50 is applied to each C4 pad within a semiconductor chip. Each C4 pad comprises a metal adhesion layer 38 and a Ni—Ti alloy layer 40. The C4 ball 50 directly contacts a top surface of the wetting layer 42, which comprises elemental Cu or elemental Ag or elemental Au. The wetting layer 42 comprises a substantially pure elemental metal without alloying. Thus, the wetting layer comprises pure Cu, pure Ag, or pure Au. The C4 ball may directly contact a portion of the passivation layer 32 along the periphery of the stack of the metal adhesion layer 38 and the Ni—Ti alloy layer 40 and the wetting layer 42.

The C4 ball 50 comprises a lead-free solder. For example, the C4 ball may comprise a Sn—Cu alloy, a Sn—Ag alloy, or a Sn—Cu—Ag alloy, in which the concentration of Cu is from 0 to about 0.7 weight percent and the concentration of Ag is from 0 atomic percent to about 3.5 atomic percent. The diameter of the C4 ball, as measured in the largest horizontal cross-section of the C4 ball 50, may be from about 50 μm to about 120 μm, although lesser and greater diameters of the C4 ball are also contemplated herein.

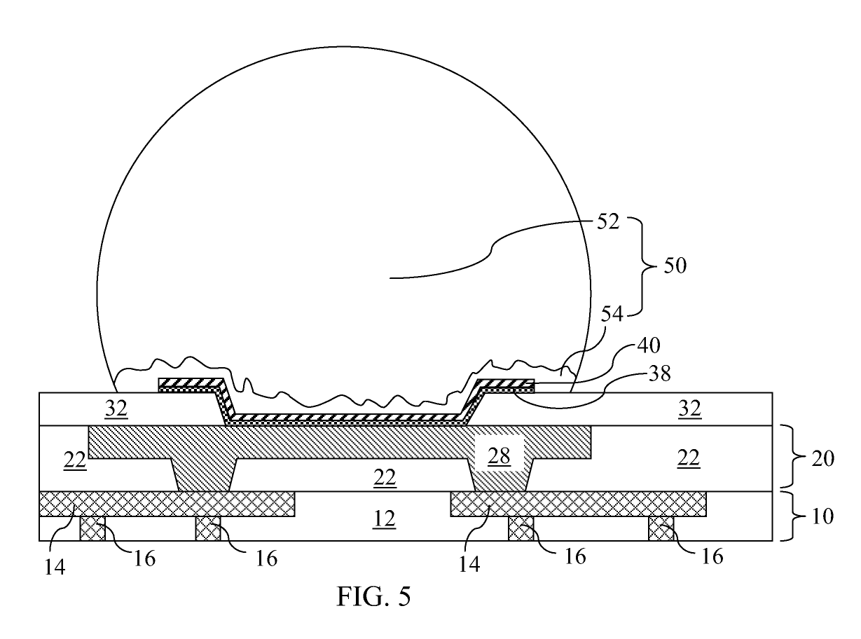

Referring to FIG. 5, the C4 ball 50 is “reflowed” to enhance adhesion to the wetting layer 42. The reflow of the C4 ball 50 is facilitated by subjecting the C4 ball 50 and the wetting layer 42 to a reflow temperature from about 210° C. to about 260° C., and typically from about 220° C. to about 250° C. The duration of the anneal at the elevated temperature may be from about 1 minute to about 6 minutes, and typically from 1 minute to about 3 minutes. Typically all of the wetting layer 42 is consumed in the first reflow by reaction with Sn-based solder. Further, a portion of the Ni—Ti alloy layer 40 reacts with the material of the C4 ball 50, which comprises the Sn—Cu alloy, the Sn—Ag alloy, or the Sn—Cu—Ag alloy. Ti atoms and Ni atoms in a top portion of the Ni—Ti react with C4 ball 50 to form a Ni—Ti alloy diffused solder region 54, which comprises a Ni—Ti—Sn—Cu/Ag alloy, i.e., an alloy of Ni, Ti, Sn, and at least one of Cu and Ag, and separates the Ni—Ti alloy from the bulk of ball 50. The rest of the C4 ball 50 is herein referred to as a homogeneous composition solder region 52, which has the same composition as the C4 ball 50 prior to the reflow. The original composition solder region 52 and the Ni—Ti alloy diffused solder region 54 collectively constitute the C4 ball 50 after the reflow.

The amount of the Ti atoms and the Ni atoms that diffuse out from the Ni—Ti alloy layer 40, i.e., the amount of consumption of the Ni—Ti alloy layer 40, depends not only on the reflow conditions but also on the composition of the Ni—Ti alloy layer 40. In the course of research leading to the present invention, it has been observed that a low weight percentage of Ni in general contributes to a high consumption rate of the Ni—Ti alloy layer 40. Weight percentage of Ni about 94% or less maintains the consumption of the Ni—Ti alloy layer 40 during the reflow to a minimum level, much less than for 100% Ni. Combined with the limitation on the weight percentage of Ti to keep the Ni—Ti alloy layer 40 non-magnetic, this results in an optimal range of the weight percentage of Ti from about 6.5% to about 30%. A preferred range for the weight percentage of Ti that reduces the amount consumption of the Ni—Ti alloy layer 40 is from about 6.5% to about 20%. Most preferably, the weight percentage of Ti that reduces the amount consumption of the Ni—Ti alloy layer 40 and keep the brittle Ni₃Ti amount to a minimum is from about 7.0% to about 10%, in which case the thickness of consumed amount of the Ni—Ti alloy layer 40 may be typically 1.0 μm or less.

Due to statistical nature of consumption of the Ni—Ti alloy layer 40 during the reflow, the interface between the Ni—Ti alloy layer 40 and the Ni—Ti alloy diffused solder region 54 has variations in height. The consumption of the Ni—Ti alloy layer 40 is limited due to the composition of the Ni—Ti alloy layer 40. Ni—Ti alloy consumption less than 1.0 μm in thickness is achieved under normal reflow conditions when a Ni—Ti alloy layer has an optimized weight percentage of Ti, for example, in the range from about 6.5% to about 30%.

Thus, the present invention provides a method for forming a reflowed C4 ball by employing a simple and economical process of sputter deposition of a non-magnetic alloy layer, which is the Ni—Ti alloy layer 40.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A semiconductor structure comprising:
a metallic adhesion layer located on a semiconductor chip;
a Ni—Ti alloy layer abutting said metallic adhesion layer, wherein a weight percentage of Ti in said Ni—Ti alloy layer is from about 6.5% to about 30%;
a wetting layer abutting said Ni—Ti alloy layer and comprising pure Cu or pure Ag or pure Au; and
a C4 ball abutting said Ni—Ti alloy layer.

2. The semiconductor structure of claim 1, wherein said semiconductor chip comprises:
a last level interconnect structure including a last level metal plate; and
a dielectric passivation layer having an opening therein, wherein said metallic adhesion layer vertically abuts said last level metal plate within said opening.

3. The semiconductor structure of claim 1, wherein said C4 ball is a homogeneous solder alloy.

4. The semiconductor structure of claim 1, wherein said C4 ball comprises:
a Ni—Ti alloy diffused solder region comprising a solder alloy, Ni, and Ti and abutting said Ni—Ti alloy layer; and
a homogeneous composition solder region comprising said solder alloy and is substantially free of Ni and Ti, abutting said Ni—Ti alloy diffused solder region, and disjoined from said Ni—Ti alloy layer.

5. The semiconductor structure of claim 4, wherein said solder alloy comprises Sn and at least one of Ag or Cu.

6. The semiconductor structure of claim 5, wherein said Ni—Ti alloy layer is non-magnetic at room temperature.

7. The semiconductor structure of claim 1, wherein said metallic adhesion layer comprises Ti, TiN, or TiW, and has a thickness from about 100 nm to about 500 nm.

8. The semiconductor structure of claim 1, wherein said weight percentage of Ti in said Ni—Ti alloy layer is from about 6.5% to about 20%.

9. The semiconductor structure of claim 8, wherein said weight percentage of Ti in said Ni—Ti alloy layer is from about 7.0% to about 10%.

10. The semiconductor structure of claim 1, wherein a thickness of said Ni—Ti alloy layer is from about 1.0 μm to about 4.0 μm.

11. The semiconductor structure of claim 10, wherein said thickness of said Ni—Ti alloy layer is from about 1.0 μm to about 3.0 μm.

12. The semiconductor structure of claim 12, wherein said thickness of said Ni—Ti alloy layer is from about 1.0 μm to about 2.0 μm.

13. A method of forming a semiconductor structure comprising:
forming a metallic adhesion layer directly on a semiconductor chip;
forming a Ni—Ti alloy layer directly on said metallic adhesion layer by sputtering, wherein a weight percentage of Ti in said Ni—Ti alloy is from about 6.5% to about 30%;
forming a wetting layer comprising pure Cu or pure Ag or pure Au directly on said Ni—Ti alloy layer; and
applying a C4 ball directly on said wetting layer.

14. The method of claim 13, wherein said semiconductor chip comprises:
a last level interconnect structure including a last level metal plate; and
a dielectric passivation layer having an opening therein, wherein said metallic adhesion layer vertically abut said last level metal plate within said opening.

15. The method of claim 13, wherein said metallic adhesion layer comprises Ti, TiN, or TiW, and has a thickness from about 100 nm to about 500 nm.

16. The method of claim 13, wherein a thickness of said Ni—Ti alloy layer is from about 1.0 μm to about 4.0 μm.

17. The method of claim 13, wherein said Ni—Ti alloy layer is deposited on said metallic adhesion layer in a vacuum chamber by sputtering of material from a sputter target containing a Ni—Ti alloy having a weight percentage of Ti from about 6.5% to about 30%.

18. The method of claim 13, further comprising reflowing said C4 ball at a temperature from about 210° C. to about 260° C., wherein less than 1.0 μm of said Ni—Ti alloy layer is consumed by reaction with said C4 ball during said reflowing.

19. The method of claim 13, further comprising forming a wetting layer directly on said Ni—Ti alloy layer, wherein said wetting layer comprises pure Cu or pure Au.

20. The method of claim 19, further comprising reflowing said C4 ball at a temperature from about 210° C. to about 260° C., wherein said wetting layer reacts with said C4 ball during said reflowing, and wherein less than 1.0 μm of said Ni—Ti alloy layer is consumed by reaction with said C4 ball during said reflowing.
